(19) United States
(12) Patent Application Publication
(10) Pub. No.: US 2016/0156347 A1
(43) Pub. Date: Jun. 2, 2016

(54) SEMICONDUCTOR DEVICE

(71) Applicant: Kabushiki Kaisha Toshiba, Minato-ku (JP)

(72) Inventor: Masayuki USUDA, Ota (JP)

(73) Assignee: Kabushiki Kaisha Toshiba, Minato-ku (JP)

(21) Appl. No.: 14/643,321

(22) Filed: Mar. 10, 2015

Related U.S. Application Data
(60) Provisional application No. 62/085,451, filed on Nov. 28, 2014.

(51) Int. Cl. H03K 17/22; G05F 3/02

(52) U.S. Cl. CPC H03K 17/223; G05F 3/02

(57) ABSTRACT

According to one embodiment, a semiconductor device includes a reference circuit configured to generate a bias voltage, a regulator configured to generate a regulator output based on the bias voltage and a power supply voltage, an integrated circuit to which the regulator output is supplied as a power supply, and a reset circuit configured to detect whether a difference between the bias voltage and the power supply voltage is equal to or higher than a threshold voltage and output a reset signal based on a detection result.

This application is based upon and claims the benefit of priority from U.S. Provisional Application No. 62/085,451, filed on Nov. 28, 2014; the entire contents of which are incorporated herein by reference.

### FIELD

Embodiments described herein relate generally to a semiconductor device.

### BACKGROUND

In a circuit to which a power supply voltage is supplied from a regulator, it is necessary to generate a reset continuously until the regulator output rises sufficiently during the power-on time. In such a circuit, when the power supply voltage does not rise sufficiently, the reset may be released erroneously.

### BRIEF DESCRIPTION OF THE DRAWINGS

FIG. 1 is a block diagram illustrating a schematic configuration of a semiconductor device according to a first embodiment;

FIG. 2 is a circuit diagram illustrating a configuration example of a regulator 2 illustrated in FIG. 1;

FIG. 3 is a diagram illustrating a voltage waveform of the semiconductor device illustrated in FIG. 1;

FIG. 4 is a block diagram illustrating a schematic configuration of a semiconductor device according to a second embodiment;

FIG. 5 is a circuit diagram illustrating a configuration example of a comparator 8′ illustrated in FIG. 4;

FIG. 6 is a diagram illustrating a voltage/current waveform of the semiconductor device illustrated in FIG. 4;

FIG. 7 is a circuit diagram illustrating a configuration example of a comparator applied to a semiconductor device according to a third embodiment;

FIG. 8 is a diagram illustrating a voltage/current waveform when the comparator illustrated in FIG. 7 is applied to the semiconductor device illustrated in FIG. 1;

FIG. 9 is a block diagram illustrating a schematic configuration of a semiconductor device according to a fourth embodiment;

FIG. 10 is a block diagram illustrating a schematic configuration of a semiconductor device according to a fifth embodiment;

FIG. 11 is a circuit diagram illustrating a configuration example of a simple comparator 19 illustrated in FIG. 10;

FIG. 12 is a diagram illustrating a voltage/current waveform of the semiconductor device illustrated in FIG. 10;

FIG. 13 is a circuit diagram illustrating a configuration example of the simple comparator 19 illustrated in FIG. 10;

FIG. 14 is a circuit diagram illustrating a second modified example of the simple comparator 19 illustrated in FIG. 11; and

FIG. 15 is a block diagram illustrating a schematic configuration of a semiconductor device according to a sixth embodiment.

### DETAILED DESCRIPTION

In general, according to one embodiment, a semiconductor device includes: a reference circuit configured to generate a bias voltage; a regulator configured to generate a regulator output based on the bias voltage and a power supply voltage; an integrated circuit to which the regulator output is supplied as a power supply; and a reset circuit configured to detect whether a difference between the bias voltage and the power supply voltage is equal to or higher than a threshold voltage and output a reset signal based on a detection result.

Exemplary embodiments of the semiconductor device will be described below in detail with reference to the accompanying drawings. The present invention is not limited to the following embodiments.

### First Embodiment

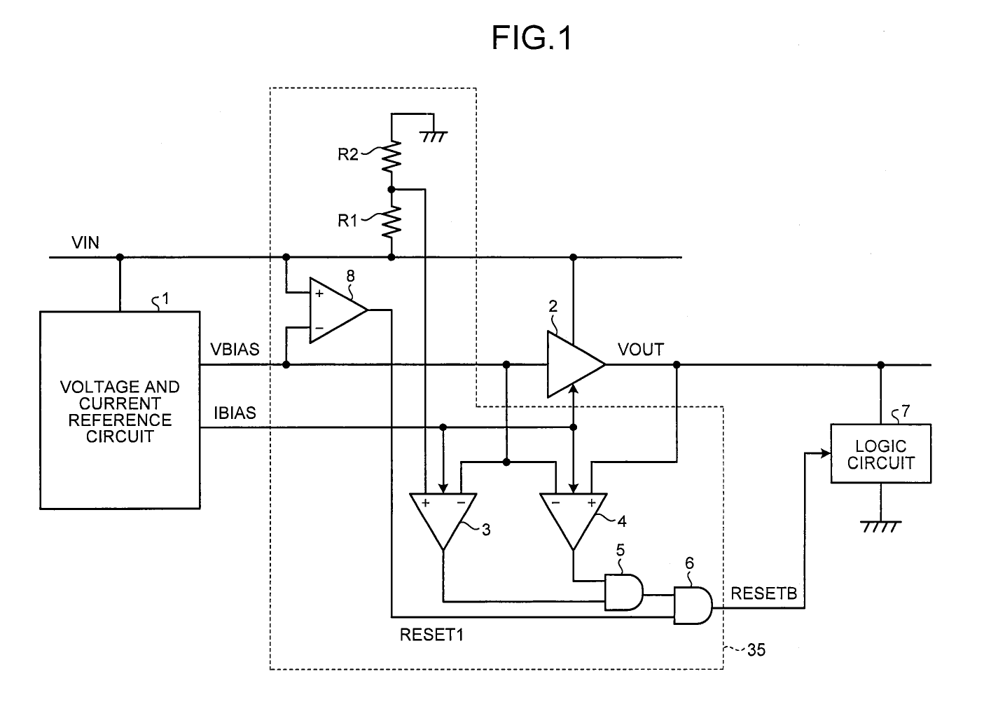

FIG. 1 is a block diagram illustrating a schematic configuration of a semiconductor device according to a first embodiment.

In FIG. 1, when a power supply voltage VIN is input, a regulator 2 can generate a regulator output VOUT and supply the same as a power supply of a logic circuit 7. A flip-flop can be provided in the logic circuit 7. The logic circuit 7 may be an input interface circuit. When the power supply voltage VIN is input, a reset circuit 35 can output a reset signal RESETB until the regulator output VOUT rises sufficiently and continuously generate and supply a reset to the logic circuit 7. In this case, the reset circuit 35 can release the reset of the logic circuit 7 by pulling up a reset signal RESET1 to the power supply voltage VIN based on a bias voltage VBIAS. When the logic circuit 7 is reset, the logic circuit 7 is maintained at its initial state. In this case, the reset signal RESETB can be set to low level. A voltage and current reference circuit 1 can generate a bias voltage VBIAS and a bias current IBIAS based on the power supply voltage VIN and output the same to the reset circuit 35. The bias voltage VBIAS and the bias current IBIAS can set an operating point of the reset circuit 35. The reset circuit 35 includes comparators 3 and 4, AND circuits 5 and 6, a comparator 8, and resistors R1 and R2. The resistors R1 and R2 divide the power supply voltage VIN and supply a divided voltage to the comparator 3. The comparator 3 compares the divided voltage in relation to the ground potential with the bias voltage VBIAS. The comparator 4 compares the regulator output VOUT with the bias voltage VBIAS. The comparator 8 detects whether a difference between the bias voltage VBIAS and the power supply voltage VIN is equal to or higher than a threshold voltage and outputs the reset signal RESET1 based on the detection result. This threshold voltage is a circuit threshold voltage used when the comparator 8 switches the reset signal RESETB. Moreover, the comparators 3 and 4 can compare input signals and the comparator 8 can compare a difference between input signals with a threshold voltage. In this case, the comparator 8 can release the reset by pulling up the reset signal RESET1 to the power supply voltage VIN based on the bias voltage VBIAS. The AND circuit 5 outputs a logical product of the output of the comparator 3 and the output of the comparator 4. The AND circuit 6 generates the reset signal RESETB based on a logical product of the output of the AND circuit 5 and the reset signal RESET1.

In the voltage and current reference circuit 1, when the power supply voltage VIN is input, the bias voltage VBIAS and the bias current IBIAS are generated. The bias voltage VBIAS is supplied to the regulator 2, the comparators 3 and 4, and the comparator 8. The bias current IBIAS is supplied to the regulator 2 and the comparators 3 and 4.

When the bias voltage VBIAS reaches a predetermined value or higher, the output of the comparator 3 rises and is output to the AND circuit 5. Moreover, when the difference voltage between the regulator output VOUT and the bias voltage VBIAS reaches a predetermined value or higher, the output of the comparator 4 rises and is output to the AND circuit 5. Further, when a difference between the regulator output VOUT and the power supply voltage VIN reaches the threshold voltage or higher, the reset signal RESET1 rises. When the output of the comparators 3 and 4 and the reset signal RESET1 rise, the reset signal RESETB rises and the reset of the logic circuit 7 is released.

Here, the use of the comparator 8 enables the level of the bias voltage VBIAS to be determined using the power supply voltage VIN as a reference. When the difference between the bias voltage VBIAS and the power supply voltage VIN reaches the threshold voltage or higher, the reset circuit 35 can pull up the reset signal RESET1 and release the reset. Here, in order for the reset signal RESET1 to be pulled up, the power supply voltage VIN needs to rise sufficiently. Due to this, when the power supply voltage VIN does not rise sufficiently, since a reset can be continuously generated without the reset signal RESET1 being pulled up, it is possible to reduce the possibility that the reset is released erroneously.

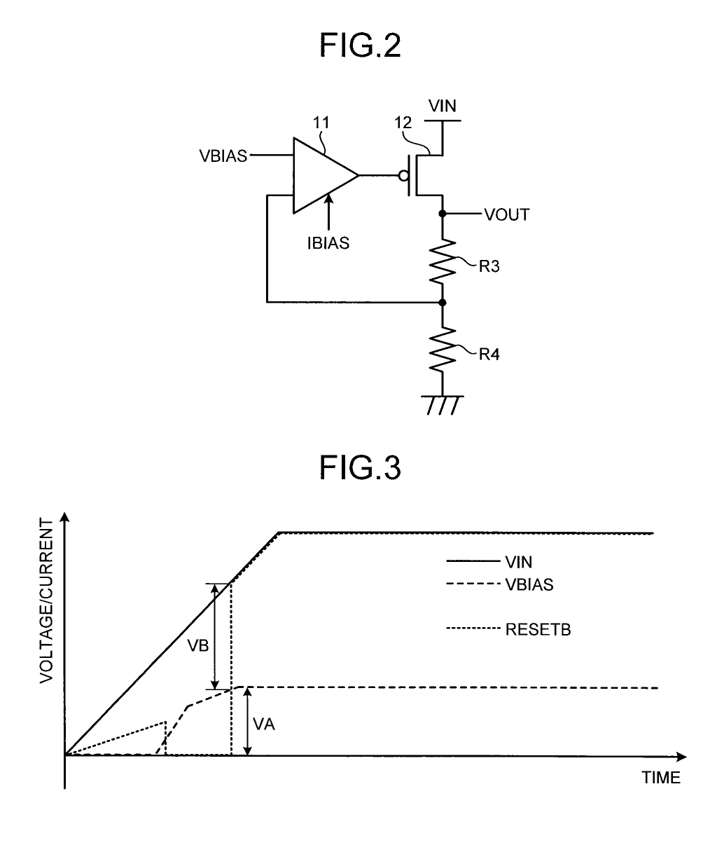

FIG. 2 is a circuit diagram illustrating a configuration example of the regulator 2 illustrated in FIG. 1.

In FIG. 2, the regulator 2 includes an amplifier 11, a P-channel transistor 12, and resistors R3 and R4. The resistors R3 and R4 divide the regulator output VOUT and supply a divided voltage to the amplifier 11. The P-channel transistor 12 is connected in series to a series circuit of the resistors R3 and R4. The power supply voltage VIN is applied to the source of the P-channel transistor 12. The output of the amplifier 11 is connected to the gate of the P-channel transistor 12.

The output of the amplifier 11 is set so that the divided voltage of the regulator output VOUT is identical to the bias voltage VBIAS. Due to this, a regulator output VOUT that is proportional to the bias voltage VBIAS can be obtained. In this case, a proportional constant can be adjusted by a voltage dividing ratio of the resistors R3 and R4.

FIG. 3 is a diagram illustrating a voltage waveform of the semiconductor device illustrated in FIG. 1.

In FIG. 3, when the power supply voltage VIN is input, the power supply voltage VIN increases gradually and settles down to a certain value with its saturation level. In this case, the bias voltage VBIAS rises with a delay from the rising of the power supply voltage VIN and settles down to a certain value with its saturation level. Here, the threshold voltage VB of the comparator 8 can be set to a value sufficiently high enough for generating a reset continuously. When the level of the power supply voltage VIN is low, the difference between the bias voltage VBIAS and the power supply voltage VIN is smaller than the threshold voltage VB. Due to this, the reset signal RESET1 output from the comparator 8 becomes low level. As a result, the reset signal RESETB output from the reset circuit 35 becomes low level and a reset is continuously supplied to the logic circuit 7. Thus, it is possible to prevent the logic circuit 7 from malfunctioning when the level of the power supply voltage VIN is low and a sufficiently high regulator output VOUT is not obtained.

When the level of the power supply voltage VIN increases and the difference between the bias voltage VBIAS and the power supply voltage VIN reaches the threshold voltage VB or higher, the reset signal RESET1 output from the comparator 8 becomes high level. As a result, when the reset signal RESETB output from the reset circuit 35 becomes high level, the reset of the logic circuit 7 is released. Thus, it is possible to allow the logic circuit 7 to operate when the level of the power supply voltage VIN increases and a sufficiently high regulator output VOUT is obtained.

The comparator 3 compares the voltage divided by the resistors R1 and R2 with the bias voltage VBIAS. Thus, malfunctioning may occur before a sufficiently high voltage VA is supplied.

### Second Embodiment

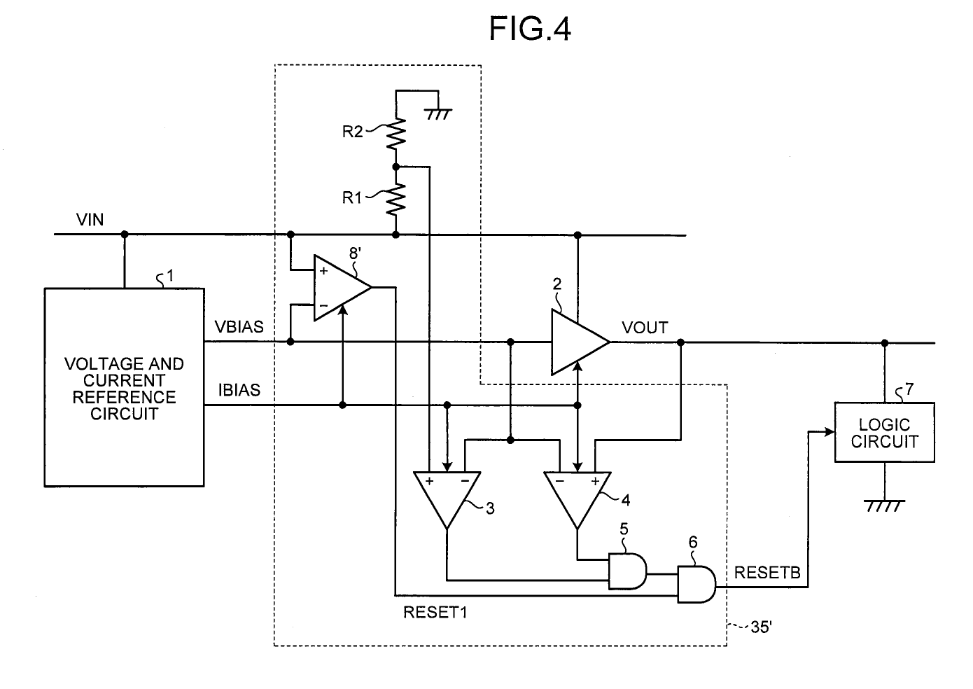

FIG. 4 is a block diagram illustrating a schematic configuration of a semiconductor device according to a second embodiment.

In FIG. 4, a reset circuit 35′ is provided instead of the reset circuit 35 illustrated in FIG. 1. In the reset circuit 35′, a comparator 8′ is provided instead of the comparator 8 illustrated in FIG. 1. The comparator 8 illustrated in FIG. 1 operates without using the bias current IBIAS supplied from the voltage and current reference circuit 1. The comparator 8′ illustrated in FIG. 4 operates based on the bias current IBIAS supplied from the voltage and current reference circuit 1.

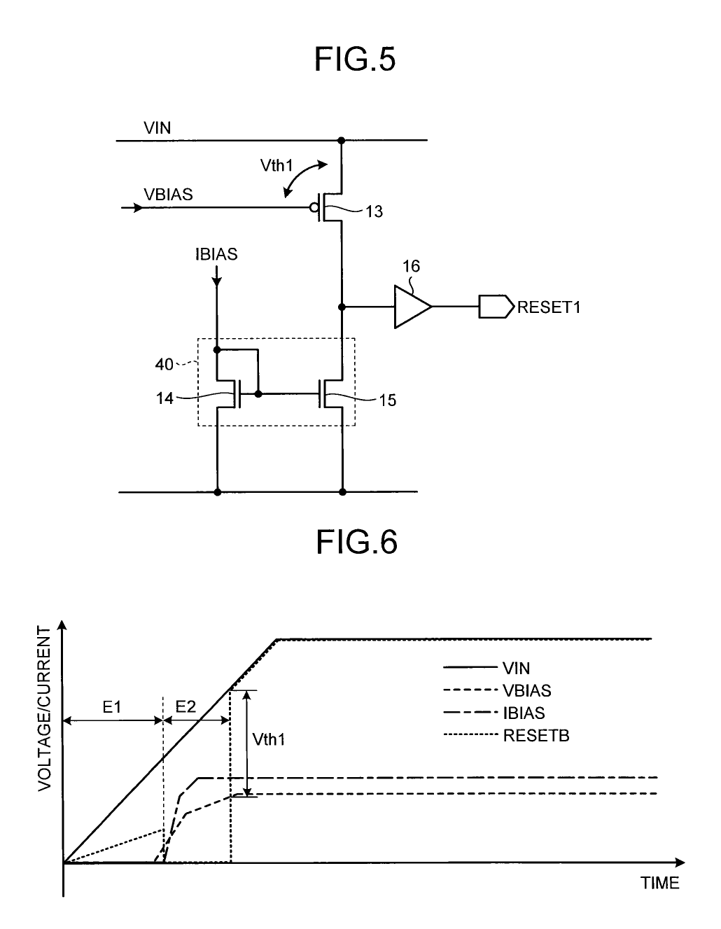

FIG. 5 is a circuit diagram illustrating a configuration example of the comparator 8′ illustrated in FIG. 4.

In FIG. 5, the comparator 8′ includes a P-channel transistor 13, a current source 40, and a buffer 16. The threshold voltage of the P-channel transistor 13 can be set to Vth1. The current source 40 includes N-channel transistors 14 and 15. The P-channel transistor 13 can pull up the reset signal RESET1. The current source 40 can pull down the reset signal RESET1. In this case, the P-channel transistor 13 can be disposed close to the power supply voltage VIN side and the current source 40 can be disposed close to the ground potential side. The N-channel transistors 14 and 15 can operate as a current mirror based on the bias current IBIAS.

The source of the P-channel transistor 13 is connected to the power supply voltage VIN. The N-channel transistor 15 is connected in series to the P-channel transistor 13. The gate of the N-channel transistor 14 is connected to the gate of the P-channel transistor 15 and is connected to its drain, and the bias current IBIAS is supplied via the drain. The reset signal RESET1 is output from the drain of the N-channel transistor 15 with the buffer 16 interposed.

Here, when the difference between the bias voltage VBIAS and the power supply voltage VIN reaches the threshold voltage Vth1 or higher, the P-channel transistor 13 is turned on and the reset signal RESET1 is pulled up. Due to this, the reset signal RESET1 rises and the reset is released. Here, in order for the reset signal RESET1 to be pulled up, the power supply voltage VIN needs to rise sufficiently. Due to this, when the power supply voltage VIN does not rise sufficiently, since a reset can be continuously generated without the reset signal RESET1 being pulled up, it is possible to prevent the reset from being released erroneously.

FIG. 6 is a diagram illustrating a voltage/current waveform of the semiconductor device illustrated in FIG. 4.

In FIG. 6, the bias current IBIAS starts rising with a delay from the start of the rising of the power supply voltage VIN. On the other hand, the current source 40 operates based on the bias current IBIAS. Due to this, when the level of the power supply voltage VIN is low (see invalid range E1), the effect of the current source 40 pulling down the reset signal RESET1 is weak, and the level of the reset signal RESET1 rises with the rise of the power supply voltage VIN.

When the level of the power supply voltage VIN increases (see valid range E2) and the bias current IBIAS starts flowing, the reset signal RESET1 is pulled down by the current source 40. Due to this, the reset signal RESET1 output from the comparator 8 becomes low level. As a result, the reset signal RESETB output from the reset circuit 35 becomes low level and a reset is supplied to the logic circuit 7. Thus, even when the bias current IBIAS starts flowing, it is possible to prevent the logic circuit 7 from malfunctioning when a sufficiently high regulator output VOUT is not obtained.

When the level of the power supply voltage VIN increases further and the difference between the bias voltage VBIAS and the power supply voltage VIN reaches the threshold voltage Vth1 or higher, the P-channel transistor 13 is turned on. Due to this, the reset signal RESET1 output from the comparator 8′ is pulled up by the P-channel transistor 13 and the reset signal RESET1 output from the comparator 8′ becomes high level. As a result, when the reset signal RESETB output from the reset circuit 35 becomes high level, the reset of the logic circuit 7 is released. Thus, it is possible to allow the logic circuit 7 to operate when the level of the power supply voltage VIN increases and a sufficiently high regulator output VOUT is obtained.

### Third Embodiment

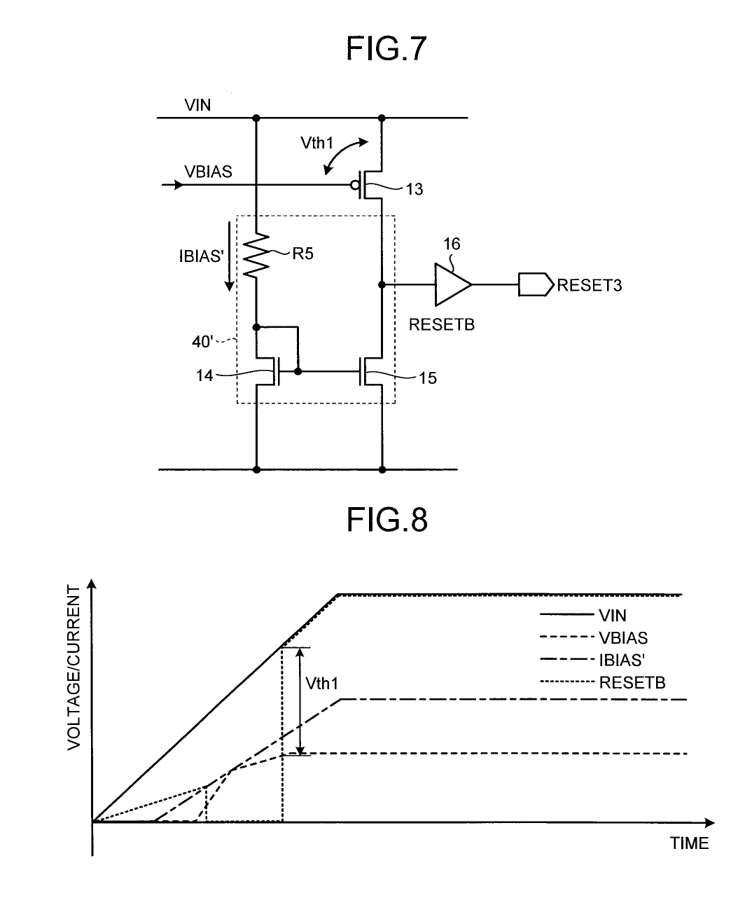

FIG. 7 is a circuit diagram illustrating a configuration example of a comparator applied to a semiconductor device according to a third embodiment.

In FIG. 7, the drain of the N-channel transistor 14 is connected to the power supply voltage VIN via a resistor R5. The other configuration is the same as that of FIG. 5. The N-channel transistors 14 and 15 and the resistor R5 can form a current source 40′. Here, in the configuration illustrated in FIG. 5, the bias current IBIAS generated by the voltage and current reference circuit 1 is supplied via the drain of the N-channel transistor 14. In contrast, in the configuration illustrated in FIG. 7, a bias current IBIAS' flowing from the power supply voltage VIN via the resistor R5 is supplied via the drain of the N-channel transistor 14. Here, the bias current IBIAS' can be adjusted based on the value of the resistor R5.

FIG. 8 is a diagram illustrating a voltage/current waveform when the comparator illustrated in FIG. 7 is applied to the semiconductor device illustrated in FIG. 1.

In FIG. 8, in the configuration illustrated in FIG. 7, the bias current IBIAS' can be supplied from the power supply voltage VIN via the resistor R5. Due to this, as compared to the configuration illustrated in FIG. 5, it is possible to bring forward the starting point of the rising of the bias current IBIAS' and to enable the current source 40′ to pull down a reset signal RESET3 earlier.

### Fourth Embodiment

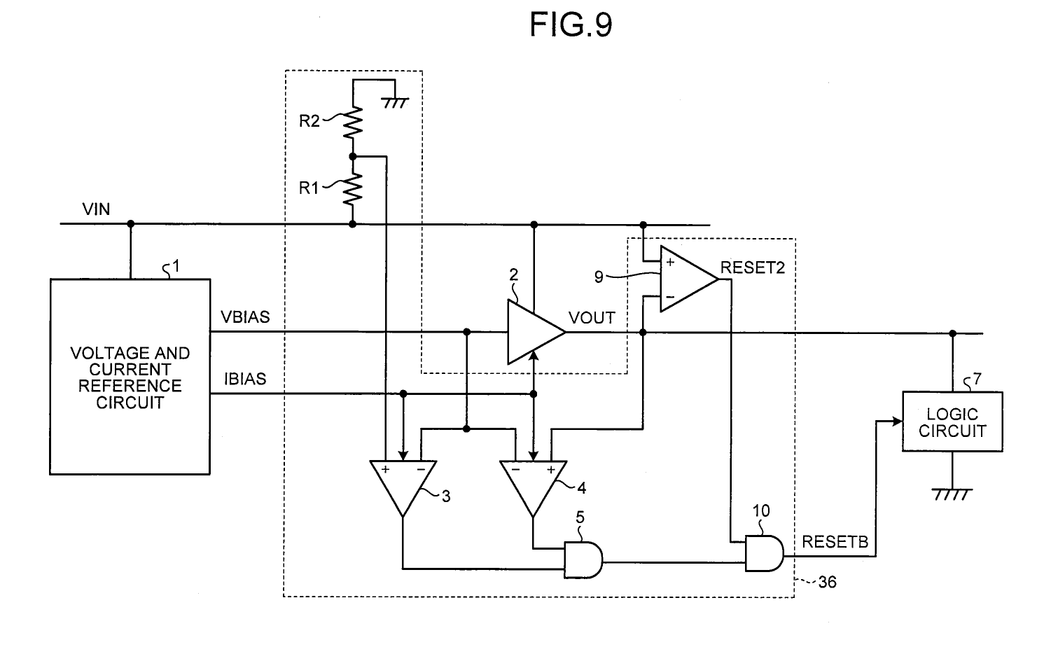

FIG. 9 is a block diagram illustrating a schematic configuration of a semiconductor device according to a fourth embodiment.

In the configuration illustrated in FIG. 9, a reset circuit 36 is provided instead of the reset circuit 35 illustrated in FIG. 1. The reset circuit 36 can release the reset of the logic circuit 7 by pulling down a reset signal RESET2 to the power supply voltage VIN based on the regulator output VOUT. In the reset circuit 36, an AND circuit 10 and a comparator 9 are provided instead of the AND circuit 6 and the comparator 8 illustrated in FIG. 1. The comparator 9 detects whether a difference between the regulator output VOUT and the power supply voltage VIN is equal to or higher than a threshold voltage and outputs a reset signal RESET2 based on the detection result. The AND circuit 10 generates a reset signal RESETB based on a logical product of the output of the AND circuit 5 and the reset signal RESET2.

In the voltage and current reference circuit 1, when the power supply voltage VIN is input, the bias voltage VBIAS and the bias current IBIAS are generated. The bias voltage VBIAS is supplied to the regulator 2 and the comparators 3 and 4. The bias current IBIAS is supplied to the regulator 2 and the comparators 3 and 4.

When the bias voltage VBIAS reaches a predetermined value or higher, the output of the comparator 3 rises and is output to the AND circuit 5. Moreover, when a difference voltage between the regulator output VOUT and the bias voltage VBIAS reaches a predetermined value or higher, the output of the comparator 4 rises and is output to the AND circuit 5. Further, when a difference between the regulator output VOUT and the power supply voltage VIN reaches a threshold voltage or higher, the reset signal RESET2 rises. When the output of the comparators 3 and 4 and the reset signal RESET2 rise, the reset signal RESETB rises and the reset of the logic circuit 7 is released.

Here, the use of the comparator 9 enables the level of the regulator output VOUT to be determined using the power supply voltage VIN as a reference. Due to this, when the power supply voltage VIN does not rise sufficiently, it is possible to reduce the possibility that the reset is released erroneously.

### Fifth Embodiment

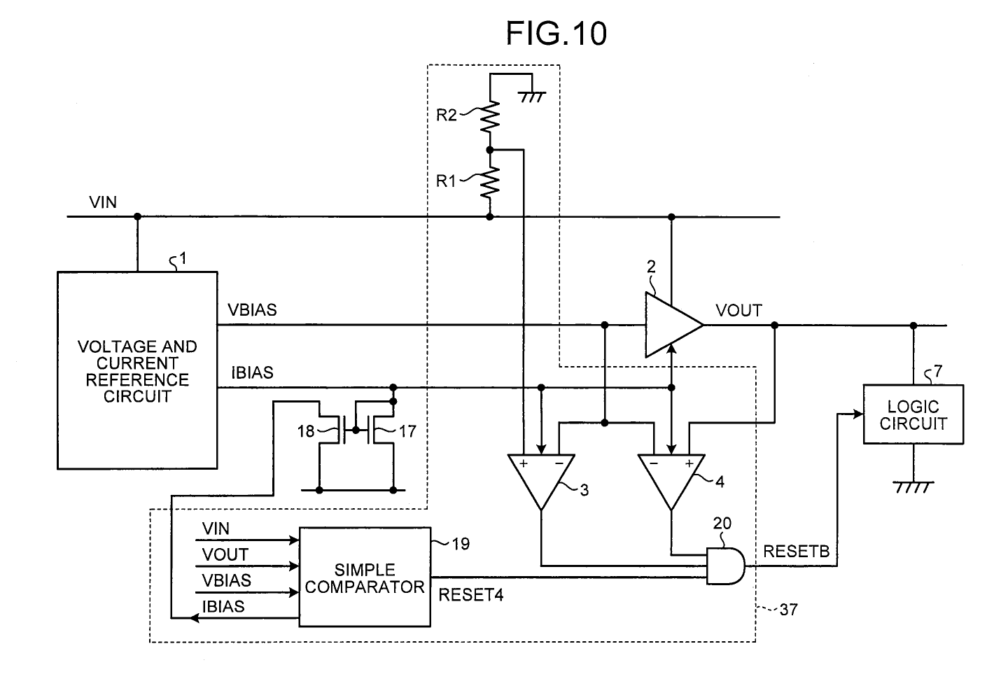

FIG. 10 is a block diagram illustrating a schematic configuration of a semiconductor device according to a fifth embodiment.

In the configuration illustrated in FIG. 10, a reset circuit 37 is provided instead of the reset circuit 35 illustrated in FIG. 1. Moreover, in the configuration illustrated in FIG. 10, N-channel transistors 17 and 18 are added to the configuration illustrated in FIG. 1. In the reset circuit 37, an AND circuit 20 and a simple comparator 19 are provided instead of the AND circuits 5 and 6 and the comparator 8 illustrated in FIG. 1. The simple comparator 19 detects the level of the bias voltage VBIAS or the regulator output VOUT in relation to the ground potential and outputs a reset signal RESET4 based on the detection result. The simple comparator 19 can release the reset of the logic circuit 7 by pulling down the reset signal RESET4 to the ground potential based on the bias voltage VBIAS. Moreover, in FIG. 10, although a configuration in which the bias voltage VBIAS and the regulator output VOUT are input to the simple comparator 19 is illustrated, only one of the bias voltage VBIAS and the regulator output VOUT may be input to the simple comparator 19. The AND circuit 20 generates a reset signal RESETB based on a logical product of the output of the comparator 3, the output of the comparator 4, and the reset signal RESET4. The N-channel transistors 17 and 18 can operate as a current mirror based on the bias current IBIAS. The drain of the N-channel transistor 18 is connected to the simple comparator 19. The gate of the N-channel transistor 17 is connected to the gate of the N-channel transistor 18 and is connected to its drain, and the bias current IBIAS is supplied from the drain.

In the voltage and current reference circuit 1, when the power supply voltage VIN is input, the bias voltage VBIAS and the bias current IBIAS are generated. The bias voltage VBIAS is supplied to the regulator 2, the comparators 3 and 4, and the simple comparator 19. The bias current IBIAS is supplied to the regulator 2 and the comparators 3 and 4. Moreover, when the bias current IBIAS is supplied to the N-channel transistor 17, the bias current IBIAS flows from the simple comparator 19 to the N-channel transistor 18.

When the bias voltage VBIAS reaches a predetermined value or higher, the output of the comparator 3 rises and is output to the AND circuit 20. Moreover, when a difference voltage between the regulator output VOUT and the bias voltage VBIAS reaches a predetermined value or higher, the output of the comparator 4 rises and is output to the AND circuit 20. Further, when the level of the bias voltage VBIAS or the regulator output VOUT reaches a predetermined value or higher, the reset signal RESET4 rises. When the output of the comparators 3 and 4 and the reset signal RESET4 rise, the reset signal RESETB rises and the reset of the logic circuit 7 is released.

Here, the use of the simple comparator 19 enables the level of the bias voltage VBIAS or the regulator output VOUT to be determined using the ground potential as a reference. Due to this, when the power supply voltage VIN does not rise sufficiently, it is possible to reduce the possibility that the reset is released erroneously.

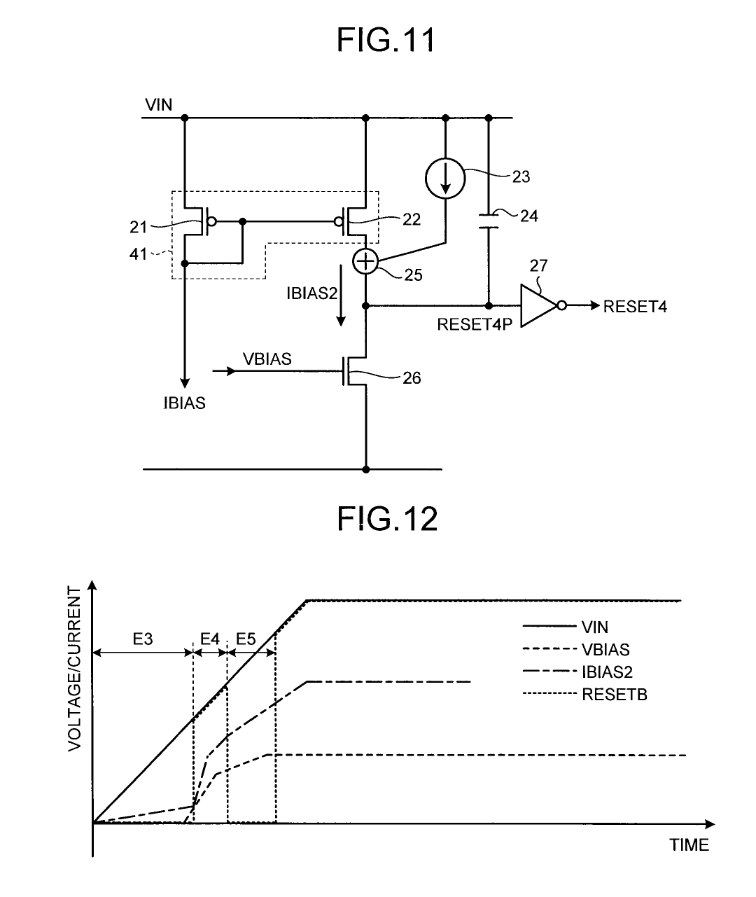

FIG. 11 is a circuit diagram illustrating a configuration example of the simple comparator 19 illustrated in FIG. 10.

In FIG. 11, the simple comparator 19 includes an N-channel transistor 26, current sources 41 and 23, a capacitor 24, an adder 25, and an inverter 27. The current sources 41 and 23 can pull up a reset signal RESET4P. The current source 23 can operate at a lower voltage than the current source 41. Here, since the current source 23 operates at a low voltage, it is possible to set the bias current of the current source 23 independently from the bias current IBIAS generated by the voltage and current reference circuit 1. The N-channel transistor 26 can pull down the reset signal RESET4P. The current sources 41 and 23 are connected in series to the N-channel transistor 26 via the adder 25. The drain of the N-channel transistor 26 is connected in series to the input of the inverter 27. The capacitor 24 is connected between the power supply voltage VIN and the input of the inverter 27.

The current source 41 includes P-channel transistors 21 and 22. The P-channel transistors 21 and 22 can operate as a current mirror based on the bias current IBIAS. The source and the drain of the P-channel transistor 22 are connected to the power supply voltage VIN and the adder 25, respectively. The gate of the P-channel transistor 21 is connected to the gate of the P-channel transistor 22 and is connected to its drain, the source thereof is connected to the power supply voltage VIN, and the bias current IBIAS is supplied from the drain. The reset signal RESET4P is output from the drain of the N-channel transistor 26, and the reset signal RESET4P is inverted by the inverter 27, whereby the reset signal RESET4 is output.

FIG. 12 is a diagram illustrating a voltage/current waveform of the semiconductor device illustrated in FIG. 10.

In FIG. 12, the current source 23 operates at a lower voltage than the current source 41. Due to this, a bias current IBIAS2 starts rising immediately after the power supply voltage VIN starts rising.

When the bias current IBIAS2 starts flowing (see valid range E3), the reset signal RESET4P is pulled up by the current source 23. Due to this, the reset signal RESET4 output from the simple comparator 19 becomes low level. As a result, the reset signal RESETB output from the reset circuit 37 becomes low level and a reset is supplied to the logic circuit 7. Thus, even before the bias current IBIAS starts flowing, it is possible to prevent the logic circuit 7 from malfunctioning when a sufficiently high regulator output VOUT is not obtained.

When the level of the power supply voltage VIN increases (see invalid range E4) and the bias voltage VBIAS starts rising, the effect of the N-channel transistor 26 pulling down the reset signal RESET4P becomes strong, and the level of the reset signal RESET4P decreases. As a result, when the reset signal RESETB output from the reset circuit 37 becomes high level, the reset of the logic circuit 7 is released.

When the bias current IBIAS increases further with an increase in the level of the power supply voltage VIN (see valid range E5), the reset signal RESET4P is pulled up by the current sources 23 and 41. Due to this, the reset signal RESET4 output from the simple comparator 19 becomes low level. As a result, the reset signal RESETB output from the reset circuit 37 becomes low level and a reset is supplied to the logic circuit 7. Thus, even before the bias current IBIAS starts flowing, it is possible to prevent the logic circuit 7 from malfunctioning when a sufficiently high regulator output VOUT is not obtained.

When the level of the power supply voltage VIN increases further, the reset signal RESET4P is pulled down by the N-channel transistor 26. Due to this, the reset signal RESET1 output from the comparator 8 is pulled up by the P-channel transistor 13, and the reset signal RESET1 output from the comparator 8 becomes high level. As a result, the reset signal RESETB output from the reset circuit 37 becomes high level and the reset of the logic circuit 7 is released. Thus, it is possible to allow the logic circuit 7 to operate when the level of the power supply voltage VIN increases and a sufficiently high regulator output VOUT is obtained.

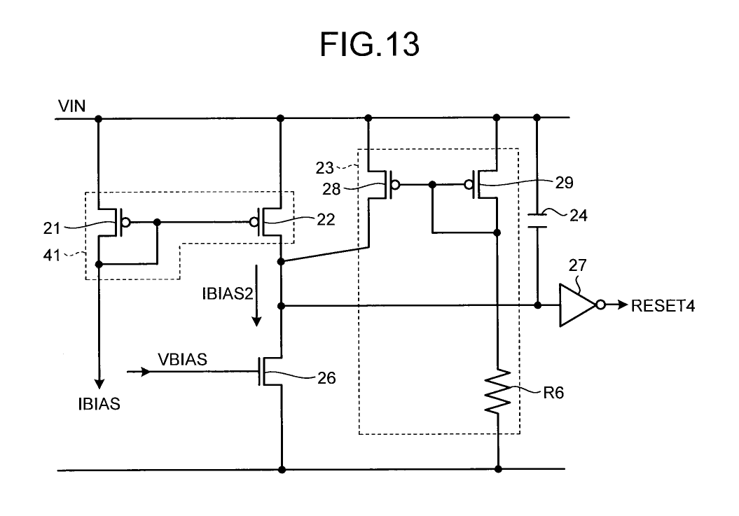

FIG. 13 is a circuit diagram illustrating a configuration example of the simple comparator 19 illustrated in FIG. 10.

In the configuration illustrated in FIG. 13, P-channel transistors 28 and 29 and a resistor R6 form the current source 23. The P-channel transistors 28 and 29 can operate as a current mirror based on the bias current flowing to the ground potential via the resistor R6. The bias current of the current source 23 can be set optionally by adjusting the value of the resistor R6. The source and the drain of the P-channel transistor 28 are connected to the power supply voltage VIN and the drain of the N-channel transistor 26, respectively. The gate of the P-channel transistor 29 is connected to the gate of the P-channel transistor 28 and is connected to its drain, and the source thereof is connected to the ground potential via the resistor R6.

When the power supply voltage VIN starts rising, current flows via the resistor R6. The current flowing via the resistor R6 by the current mirror operation of the P-channel transistors 28 and 29 flows into the P-channel transistor 28, whereby the bias current IBIAS2 starts rising.

When the bias current IBIAS2 starts flowing, the reset signal RESET4P is pulled up by the current source 23. Due to this, the reset signal RESET4 output from the simple comparator 19 becomes low level. As a result, the reset signal RESETB output from the reset circuit 37 becomes low level, and a reset is supplied to the logic circuit 7. Thus, even before the bias current IBIAS starts flowing, it is possible to prevent the logic circuit 7 from malfunctioning when a sufficiently high regulator output VOUT is not obtained. The voltage/current waveform of the configuration illustrated in FIG. 13 is the same as that illustrated in FIG. 12.

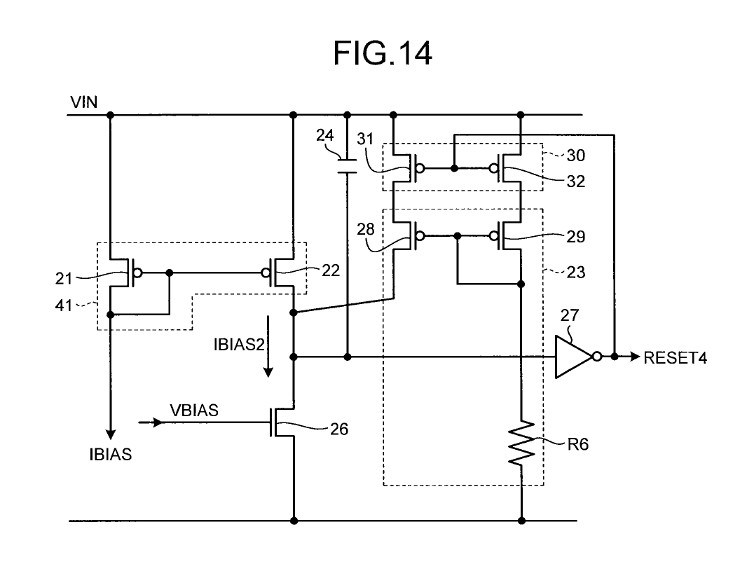

FIG. 14 is a circuit diagram illustrating a second modified example of the simple comparator 19 illustrated in FIG. 11.

In the configuration illustrated in FIG. 14, a switch circuit 30 is added to the configuration illustrated in FIG. 13. The switch circuit 30 can turn off the current source 23 based on the reset signal RESET4. The switch circuit 30 includes P-channel transistors 31 and 32. The P-channel transistor 32 is connected in series to the P-channel transistor 29. The P-channel transistor 31 is connected in series to the P-channel transistor 28. The sources of the P-channel transistors 31 and 32 are connected to the power supply voltage VIN. The gates of the P-channel transistors 31 and 32 are connected to the output of the inverter 27.

When the level of the power supply voltage VIN is low, the level of the reset signal RESET4 decreases. Due to this, the P-channel transistors 31 and 32 are turned on and the current source 23 operates effectively. As a result, the same voltage/current waveform as that illustrated in FIG. 12 is obtained in the valid ranges E3 and E5 and the invalid range E4. When the level of the power supply voltage VIN increases and the level of the reset signal RESET4 increases, the P-channel transistors 31 and 32 are turned off. Due to this, the current source 23 enters a non-operating state and the bias current IBIAS2 decreases to the bias current IBIAS, whereby power consumption can be reduced.

### Sixth Embodiment

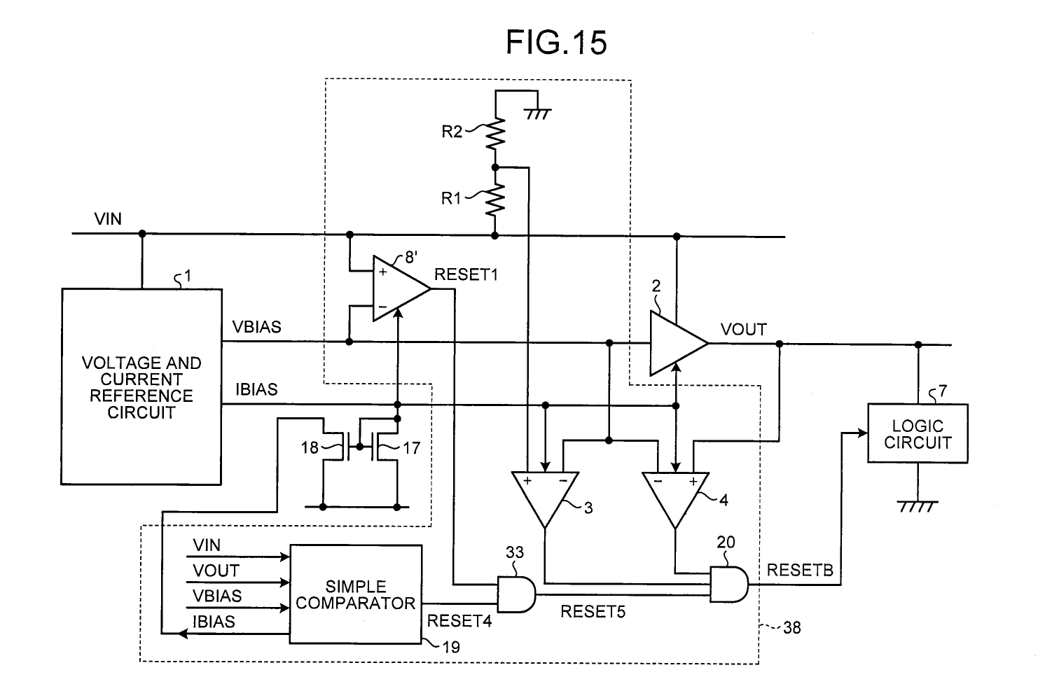

FIG. 15 is a block diagram illustrating a schematic configuration of a semiconductor device according to a sixth embodiment.

In the configuration illustrated in FIG. 15, a reset circuit 38 is provided instead of the reset circuit 37 illustrated in FIG. 10. In the reset circuit 38, an AND circuit 33 and the comparator 8′ illustrated in FIG. 4 are added to the reset circuit 37. In the AND circuit 33, a logical product of the reset signal RESET1 output from the comparator 8 and the reset signal RESET4 output from the simple comparator 19 is obtained and output to the AND circuit 20. For example, the comparator 8′ can use the configuration illustrated in FIG. 5 and the simple comparator 19 can use the configuration illustrated in FIG. 14. Here, the comparator 8′ is in the invalid range E1 when the level of the power supply voltage VIN is low and the simple comparator 19 is in the valid range E3 when the level of the power supply voltage VIN is low. Due to this, by combining the comparator 8′ and the simple comparator 19, it is possible to compensate for the invalid range E1 of the comparator 8′ with the valid range E3 of the simple comparator 19. Thus, it is possible to reduce the possibility that the reset is released erroneously.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor device comprising:
a reference circuit configured to generate a bias voltage;
a regulator configured to generate a regulator output based on the bias voltage and a power supply voltage;
an integrated circuit to which the regulator output is supplied as a power supply; and
a reset circuit configured to detect whether a difference between the bias voltage and the power supply voltage is equal to or higher than a threshold voltage and output a reset signal based on a detection result.

2. The semiconductor device according to claim 1, wherein
the reset circuit releases the reset of the integrated circuit by pulling up the reset signal to the power supply voltage based on the detection result.

3. The semiconductor device according to claim 1, wherein
the reset circuit includes a comparator configured to detect whether a difference between the bias voltage and the power supply voltage is equal to or higher than a threshold voltage, and
the comparator includes:
a current source configured to pull down the reset signal to a ground potential; and
a transistor to which a current is supplied from the current source and which is configured to pull up the reset signal to the power supply voltage.

4. The semiconductor device according to claim 1, wherein
the reset circuit includes a comparator configured to detect whether a difference between the bias voltage and the power supply voltage is equal to or higher than a threshold voltage,
the comparator includes:
a current source connected close to a ground potential side; and
a transistor connected in series to the current source and connected close to the power supply voltage side, and
the reset signal is output from a connection point between the current source and the transistor.

5. The semiconductor device according to claim 4, wherein
the threshold voltage of the comparator is a threshold voltage of the transistor.

6. The semiconductor device according to claim 4, wherein
the comparator includes:
a P-channel transistor of which the source is connected to the power supply voltage;
a first N-channel transistor connected in series to the P-channel transistor; and
a second N-channel transistor of which the gate is connected to a gate of the first N-channel transistor and the drain is connected to the gate, and to which a bias current is supplied via the drain.

7. The semiconductor device according to claim 4, wherein
the comparator includes:
a P-channel transistor of which the source is connected to the power supply voltage;
a first N-channel transistor connected in series to the P-channel transistor; and
a second N-channel transistor of which the gate is connected to a gate of the first N-channel transistor and the drain is connected to the gate, and to which a bias current is supplied from the power supply voltage to the drain via a resistor.

8. A semiconductor device comprising:
a reference circuit configured to generate a bias voltage;
a regulator configured to generate a regulator output based on the bias voltage and a power supply voltage;
an integrated circuit to which the regulator output is supplied as a power supply; and
a reset circuit configured to detect whether a difference between the regulator output and the power supply voltage is equal to or higher than a threshold voltage and output a reset signal based on a detection result.

9. The semiconductor device according to claim 8, wherein
the reset circuit releases the reset of the integrated circuit by pulling up the reset signal to the power supply voltage based on the detection result.

10. The semiconductor device according to claim 8, wherein
the reset circuit includes a comparator configured to detect whether a difference between the regulator output and the power supply voltage is equal to or higher than a threshold voltage, and
the comparator includes:
a current source configured to pull down the reset signal to a ground potential; and
a transistor to which a current is supplied from the current source and which is configured to pull up the reset signal to the power supply voltage.

11. The semiconductor device according to claim 8, wherein
the reset circuit includes a comparator configured to detect whether a difference between the regulator output and the power supply voltage is equal to or higher than a threshold voltage,
the comparator includes:
a current source connected close to a ground potential side; and
a transistor connected in series to the current source and connected close to the power supply voltage side, and
the reset signal is output from a connection point between the current source and the transistor.

12. The semiconductor device according to claim 11, wherein
a threshold voltage of the comparator is a threshold voltage of the transistor.

13. The semiconductor device according to claim 11, wherein
the comparator includes:
a P-channel transistor of which the source is connected to the power supply voltage;
a first N-channel transistor connected in series to the P-channel transistor; and
a second N-channel transistor of which the gate is connected to a gate of the first N-channel transistor and the drain is connected to the gate and to which a bias current is supplied via the drain.

14. The semiconductor device according to claim 11, wherein
the comparator includes:
a P-channel transistor of which the source is connected to the power supply voltage;
a first N-channel transistor connected in series to the P-channel transistor; and
a second N-channel transistor of which the gate is connected to a gate of the first N-channel transistor and the drain is connected to the gate, and to which a bias current is supplied from the power supply voltage to the drain via a resistor.

15. The semiconductor device according to claim 8, wherein
the regulator output is proportional to the bias voltage.

16. A semiconductor device comprising:
a reference circuit configured to generate a first bias voltage;
a regulator configured to generate a regulator output based on the first bias voltage and a power supply voltage;
an integrated circuit to which the regulator output is supplied as a power supply; and
a reset circuit configured to release the reset of the integrated circuit by pulling down a reset signal to a ground potential based on a second bias voltage generated separately from the first bias voltage.

17. The semiconductor device according to claim 16, wherein
the reset circuit includes:
a first current source configured to pull up the reset signal;
an N-channel transistor configured to pull down the reset signal; and
a second current source configured to operate at a lower voltage than the first current source and pull up the reset signal.

18. The semiconductor device according to claim 17, wherein
the first current source includes:
a first P-channel transistor which is connected in series to the N-channel transistor and of which the source is connected to the power supply voltage; and
a second P-channel transistor of which the gate is connected to a gate of the first P-channel transistor, the source is connected to the power supply voltage, and the drain is connected to the gate and to which a bias current is supplied via the drain, and
the second current source includes:
a third P-channel transistor which is connected in series to the N-channel transistor and of which the source is connected to the power supply voltage; and
a fourth P-channel transistor of which the gate is connected to a gate of the third P-channel transistor, the source is connected to the power supply voltage, and the drain is connected to the gate and to which a bias current is supplied to the drain via a resistor that is connected to the ground potential.

19. The semiconductor device according to claim 17, further comprising:
a switch circuit that turns off the second current source based on the reset signal.

20. The semiconductor device according to claim 19, wherein
the first current source includes:
a first P-channel transistor which is connected in series to the N-channel transistor and of which the source is connected to the power supply voltage; and
a second P-channel transistor of which the gate is connected to a gate of the first P-channel transistor, the source is connected to the power supply voltage, and the drain is connected to the gate and to which a bias current is supplied via the drain,
the second current source includes:
a third P-channel transistor connected in series to the N-channel transistor; and
a fourth P-channel transistor of which the gate is connected to a gate of the third P-channel transistor and the drain is connected to the gate and to which a bias current is supplied to the drain via a resistor that is connected to the ground potential,
the switch circuit includes:
a fifth P-channel transistor which is connected in series to the third P-channel transistor and of which the source is connected to the power supply voltage; and
a sixth P-channel transistor which is connected in series to the fourth P-channel transistor and of which the gate is connected to a gate of the fifth P-channel transistor and the source is connected to the power supply voltage, and
the reset signal is applied to the gates of the fifth and sixth P-channel transistors.
